(19) United States
(12) Patent Application Publication
(10) Pub. No.: US 2015/0235885 A1
(43) Pub. Date: Aug. 20, 2015

(54) PURGE SYSTEM, POD USED WITH PURGE SYSTEM, AND LOAD PORT APPARATUS

(71) Applicant: TDK Corporation, Tokyo (JP)

(72) Inventor: Tadamasa IWAMOTO, Tokyo (JP)

(73) Assignee: TDK Corporation, Tokyo (JP)

(21) Appl. No.: 14/627,293

(22) Filed: Feb. 20, 2015

(30) Foreign Application Priority Data
Feb. 20, 2014 (JP) 2014-030354

(51) Int. Cl. H01L 21/673; B65B 31/04

(52) U.S. Cl. CPC H01L 21/67389; H01L 21/67376; B65B 31/04

(57) ABSTRACT

A system prevents oxidative gases in a FOUP which is fixed to an FIMS system in an open state from increasing over time. A tower type gas supply port extending from the bottom of the FOUP to inside is provided. Nitrogen can be supplied into the FOUP through the gas supply port in addition to nitrogen purge through the pod opening, when the pod is mounted on the FIMS. Two gas flows thus formed cooperate to create a gas flow flowing along the side of the FOUP opposite to the opening and to the opening. Thus, the gas in the interior of the FOUP is remounted with nitrogen uniformly.

### BACKGROUND OF THE INVENTION

1. Field of the Invention

The present invention relates to what is called a FIMS (Front-Opening Interface Mechanical Standard) system used between semiconductor processing apparatuses. The FIMS system is used to open/close a pod or an airtight container called FOUP (Front-Opening Unified Pod) in which wafers are housed to allow transfer of wafers into and out of the pod. The present invention relates to an FIMS system functioning as a purge system that performs purging operation for cleaning the interior of the pod, a pod used with such an FINS system, and a load port apparatus adapted to the pod.

2. Description of the Related Art

The pod includes a body part in which wafers are to be housed and a lid that closes the opening of the body part. The operations of opening and closing the lid of the pod and the transfer of wafers into/out of the pod are performed through a mini-environment in which a transfer robot or device with which a semiconductor processing apparatus is equipped is provided. A load port apparatus has a wall partly defining the mini-environment and having an opening portion leading to the mini-environment, a mount base on which a pod is mounted with its opening directly facing the opening portion of the wall, and a door that closes and opens the opening of the wall.

Typically, the interior of the pod loaded with wafers or the like is filled with dry nitrogen or the like gas that is controlled to be highly clean to prevent the entry of contaminants and oxidative gases etc. into the pod. However, while wafers in the pod are transferred to one of various kinds of processing apparatuses to undergo certain processing, the interior of the pod and the interior of the processing apparatus are kept in communication with each other all the time. The transfer device used to transfer wafers into/out of the pod is provided in the mini-environment. The mini-environment is provided with a fan and a filter, by which clean air with controlled particles is introduced into the mini-environment. However, when such air enters the pod, there is a possibility that oxygen and/or moisture in the air may adhere to the surface of the wafers. With size reduction and improving performance of semiconductor devices, oxygen or the like entering in the pod, which has not cause serious problems with conventional devices, is becoming taken care of.

Such oxidative gases form an ultrathin oxide film on the surface of the wafers or on the various kinds of layers formed on the wafers. There is a possibility that the presence of such an oxide film may prevent micro devices from having desired characteristics. A possible countermeasure to this is to introduce a gas with a controlled partial pressure of oxidative gas such as oxygen into the pod to prevent an increase in the oxygen partial pressure. A specific method is disclosed in Japanese Patent Application Laid-Open No. 2012-019046. In the apparatus disclosed in this patent literature, an inert gas such as nitrogen gas is supplied to the space in front of the opening of the pod, when the pod is opened and closed. In this apparatus, when the lid of the pod is detached to open the opening of the pod, the space in front of the pod opening is filled with inert gas supplied by a gas supply nozzle, thereby reducing the oxygen concentration in the interior of the pod.

In the apparatus disclosed in Japanese Patent Application Laid-Open No. 2012-019046, a chamber is provided in the space in the load port in front of the opening of the pod to provide a space separated from the mini-environment, and the interior of the pod and the space separated from the mini-environment by this chamber are purged using an inert gas. This apparatus can reduce the oxygen partial pressure in the space in front of the pod opening when the lid is open and reduce the oxygen partial pressure in the interior of the pod when the lid is closed.

In the actual semiconductor wafer processing, it is necessary that the pod opening and the mini-environment are kept spatially in communication with each other in order to allow transfer of wafers. Therefore, in cases, for example, where all the wafers in the pod are to be processed consecutively, the chamber needs to be kept in a retracted state, necessarily leading to a decrease in the reduction of the oxygen partial pressure in the interior of the pod. With slimming of wiring in semiconductor devices in recent years, a further reduction in the oxygen partial pressure is required in order to prevent oxidation of thin wiring, even when the lid is kept open during consecutive wafer processing, during which no serious problem occurs with previous semiconductor devices.

### SUMMARY OF THE INVENTION

The present invention has been made in view of the above-described circumstances, and its object is to provide a load port apparatus that can keep the partial pressure of oxidative gases such as oxygen in the pod at a predetermined low level even during consecutive processing of wafers.

To achieve the above-described object, according to the present invention, there is provided a purge system comprising a pod for housing contents and a load port apparatus that performs an operation of purging gas in the interior of said pod, wherein said pod has an opening leading to a space in which said contents are housed, a lid closing said opening, and an in-pod gas supply port arranged at a corner on the side opposite to said opening in said housing space and blowing a specific gas in a direction parallel to a direction in which said contents extend, said load port apparatus is adapted to detach said lid from the pod thereby opening said opening and allowing transfer of said contents into/out of the pod and has a mount base on which said pod is mounted, a mini-environment arranged adjacent to said mount base in which a mechanism for transferring said contents is accommodated, an opening portion that is provided on a wall that is adjacent to said mount base and partly defines said mini-environment and able to directly face said opening of said pod mounted on said mount base, a door that can hold said lid, close said opening portion, and open said opening portion while holding said lid to thereby bring the interior of said pod and said mini-environment into communication with each other, a supply port that cooperates with said in-pod gas supply port to supply said specific gas into the interior of said pod, and a purge nozzle arranged on the mini-environment side of said opening portion near a side edge of said opening portion to supply said specific gas to the interior of said pod on/from which said lid is attached/detached, said specific gas supplied through said in-pod gas supply port and said specific gas supplied through said purge nozzle each have a non-uniform flow rate distribution along a direction of arrangement of said contents when blown from them, and a gas flow flowing along the side of said pod opposite to said opening and then flowing to said opening of said pod is created in said pod by the supplied gas flows having said non-uniform flow rate distribution.

In the above-described purge system, it is preferred that a range over which said specific gas is blown out of said in-pod gas supply port be narrower than a range over which said specific gas is blown out of said purge nozzle. It is also preferred that said in-pod gas supply port extends from one of the inner surfaces of said pod extending parallel to planes in which said contents each having a plate-like shape extend in said pod.

To achieve the above-described object, according to the present invention, there is provided a pod that allows transfer of contents into/out of it through an opening, comprising a lid that closes said opening and an in-pod gas supply port that supplies, when a specific gas is supplied into the pod through said opening with a predetermined flow rate distribution along an arrangement direction along which said contents each having a plate-like shape are arranged in parallel to each other, said specific gas from a side of the pod opposite to said opening with a flow rate distribution corresponding to said predetermined flow rate distribution in said arrangement direction, thereby creating in said pod a gas flow flowing along the side opposite to said opening and then flowing to the opening of said pod.

In the above-described pod, it is preferred that a range along said over which said specific gas is blown out of said in-pod gas supply port be narrower than a range over which said contents are arranged in said arrangement direction. It is also preferred that said in-pod gas supply port is arranged to extend from the bottom of said pod into the interior of the pod when the pod is mounted on a plane extending in parallel with said contents.

To achieve the above-described object, according to the present invention, there is provided a load port apparatus that performs an operation of purging gas in the interior of the above-described pod comprising: a mount base on which said pod is mounted; a mini-environment arranged adjacent to said mount base in which a mechanism for transferring said contents is accommodated; an opening portion that is provided on a wall that is adjacent to said mount base and partly defines said mini-environment and able to directly face said opening of said pod mounted on said mount base; a door that can hold said lid, close said opening portion, and open said opening portion while holding said lid to thereby bring the interior of said pod and said mini-environment into communication with each other; a supply port that cooperates with said in-pod gas supply port to supply said specific gas into the interior of said pod; and a purge nozzle arranged on the mini-environment side of said opening portion near a side edge of said opening portion to supply said specific gas to the interior of said pod on/from which said lid is attached/detached, wherein said purge nozzle supplies a specific gas into the interior of said pod through said opening with a predetermined flow rate distribution.

In the system according to the present invention, even when the lid is detached and interior of the pod and the mini-environment are in communication with each other, inert gas or the like of high purity is directly supplied into the interior of the pod. Therefore, it is possible to keep the partial pressure of oxidative gases such as oxygen in the pod at a predetermined low level even during the time in which wafers are processed consecutively.

Further features of the present invention will become apparent from the following description of exemplary embodiments with reference to the attached drawings.

### BRIEF DESCRIPTION OF THE DRAWINGS

FIG. 1A is a schematic diagram illustrating a method of purging in a load port apparatus according to the present invention.

FIG. 1B is a schematic diagram illustrating the method of purging in the load port apparatus according to the present invention.

FIG. 2 is a schematic perspective view showing the relevant portion of a load port apparatus according to an embodiment of the present invention.

FIG. 3 is a cross sectional view showing the load port, a pod, a lid of the pod, and a portion of an opener according to the embodiment of the present invention, taken on a plane perpendicular to the pod opening.

FIG. 4 is a diagram illustrating the directions of purge gas supply from purge nozzles into the pod.

FIG. 5 is a schematic diagram showing supply of gas through the purge nozzles shown in FIG. 2, where a first opening portion is seen from the mini-environment side.

FIG. 6 is a cross sectional view of a mount base of the load port apparatus shown in FIGS. 1A and 1B taken on a vertical plane containing a gas supply valve.

FIG. 7 is a diagram schematically showing the top of the mount base according to the present invention seen from above.

FIG. 8 is a flow chart of a purging operation performed in the load port apparatus according to the embodiment of the present invention.

### DESCRIPTION OF THE EMBODIMENTS

Preferred embodiments of the present invention will now be described in detail in accordance with the accompanying drawings.

The embodiment described in the following is not intended to limit the scope of the present invention as claimed, and all the combinations of the features described in the description of the embodiment are not necessarily essential to the present invention.

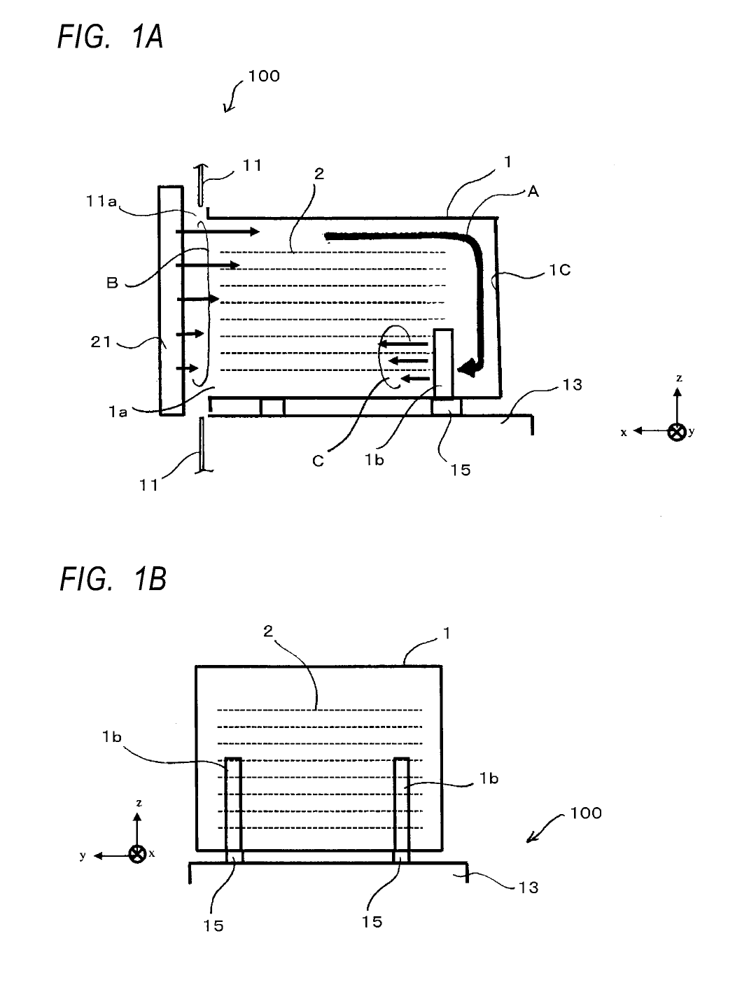

FIG. 1A is a diagram showing a mode of the purge operation in an embodiment of the present invention. Specifically, FIG. 1A is a cross sectional view showing a first opening portion, which will be described later, a pod, and the opening of the pod. FIG. 1B is a diagram schematically showing the structure of the pod seen from the opening side. Arrows in FIG. 1A schematically show how inert gas is supplied to the aforementioned parts. The purge operation described in the following refers to a process of introducing an inert gas such as nitrogen or a specific gas into the pod to purge the gas existing inside the pod. In FIGS. 1A and 1B, wafers 2 as contents are housed in the inner space of the pod 1. The wafers are arranged in parallel to each other along the vertical direction in a range of a predetermined holding region, and each wafer 2 extends in the horizontal direction. The horizontal and vertical directions mentioned above respectively refer to the direction in which the bottom of the pod 1 extends and the direction in which the open face of the pod 1 extends, which may different from the actual horizontal direction and the vertical direction.

FIGS. 1A and 1B also show a wall 11 that defines a mini-environment in the load port apparatus 100 according to the present invention and a mount base 13. In these drawing, the lid (not shown) of the pod 1 has already been detached, and an opening portion 11a provided on the wall 11 and the interior of the pod 1 are in communication with each other. The mount base 13 is provided with mount base gas supply ports (first gas supply port) 15, which cooperate with in-pod gas supply towers 1b provided on the opposed surface of the pod 1 to enable supply of a specific inert gas into the interior of the pod 1. As shown in FIG. 1B, the in-pod gas supply towers 1b are located near the two corners on the side 1c of the pod 1 opposite to the opening so that they do not interfere with the wafers 2 housed in the pod 1. The in-pod gas supply towers 1b extend upwardly from the bottom of the pod 1 and supply inert gas into the interior of the pod 1 directionally so that a first gas flow A directed toward the opening 1a of the pod 1 is formed. The first gas flow A will be specifically described later.

In the present invention, in the state shown in FIGS. 1A and 1B, the inert gas is supplied in such a way as to flow in two directions indicated by the arrows in FIG. 1A. Firstly, a second gas flow B flowing from the mini-environment into the interior of the pod 1 through the first opening portion 11a is formed. The second gas flow B is the main gas supply channel for purging the interior of the pod 1 with inert gas. In the second gas flow B, in order to effectively purge the spaces between the wafers 2, the inert gas is supplied directionally from the opening la toward the side 1c of the pod 1 opposite to the opening la along the direction in which the wafers 2 extend. When emitted from purge nozzles, which will be described later, the flow rate of the inert gas supplied to the upper region of the pod 1 and the flow rate of the inert gas supplied to the lower region of the pod 1 are different from each other. In this embodiment, the flow rate is higher in the upper region and gradually decreases toward the lower region.

A third gas flow C is formed by the inert gas supplied into the interior of the pod 1 through the aforementioned in-pod gas supply towers 1b. As described above, the in-pod gas supply towers 1b are located outside the edges of the wafers 2 when seen along the height direction. The in-pod gas supply towers 1b supply the inert gas from this location in the direction parallel to the planes of the wafers 2 substantially toward the opening 1a. In this embodiment, the flow rate of the inert gas supplied through the in-pod gas supply towers 1b at upper positions in the pod and the flow rate of the inert gas supplied through the in-pod gas supply towers at lower positions are different. In this embodiment, the flow rate is higher at upper positions and gradually decreases toward lower positions.

Due to this flow rate difference and the flow rate difference of the second gas flow B along the vertical direction, the first gas flow A that flows toward the side 1c opposite to the opening 1c in the upper region of the pod 1, toward the bottom of the pod 1 in the region near the side 1c opposite to the opening, and toward the opening 1a in the lower region of the pod 1 is formed in the pod 1. This first gas flow A facilitates the circulation of the gas supplied into the pod 1 and facilitates efficient inert gas purge of the entirety of the interior of the pod 1 with the gas. It is preferred that the in-pod gas supply towers lb be arranged in a pair at corners of the pod 1 symmetrically with respect to the center line of the pod 1 when seen along the height direction. If they are located in such a way as to pair the in-pod gas supply tower 1b with purge nozzles 21, which will be described later, the first gas flow A is formed in a more preferable manner.

In the present invention, supply of the inert gas forming the aforementioned three gas flows is performed when transfer of the wafers 2 into/out of the pod 1 is performed continuously in the state in which the lid 3 is detached. Therefore, even in the case where a plurality of wafers 2 in the pod 1 are processed consecutively, inert gas is supplied sufficiently in the entirety of the interior of the pod 1, so that the increase in the oxygen partial pressure is prevented or reduced evenly. A preferable mode of the flow rate difference or flow rate variation of the inert gas supplied through the purge nozzles 21 and the in-pod gas supply towers 1b depending on the supply position is described in this specification. However, the mode of the flow rate is not limited to the mode described here. What is essential is that the first gas flow A can be formed effectively with the structural features of the apparatus such as the size and the inner shape of the pod 1 and the size and the spacing of the wafers 2 held in the pod 1.

The effective height of the in-pod gas supply towers 1b that defines the range over which they can supply inert gas into the pod 1 is designed to be lower than the height of the interior space of the pod 1. On the other hand, it is preferred that the effective height range of the purge nozzles 21 for supplying inert gas extend beyond the upper and lower ends of the opening 1a of the pod 1. More specifically, it is preferred that the effective height of the purge nozzles 21 extend beyond the range over which the wafers 2 held in the pod exist by a predetermined length in the vertical direction. Moreover, it is preferred that the height of the in-pod gas supply towers lb be smaller than the effective height of the purge nozzles 21. Any arrangement in which the flow rate of the supplied inert gas is varied in the gas supply ranges of the purge nozzles 21 and the in-pod gas supply towers 1b to enable the formation of the overall first gas flow A is included in the scope of the invention.

In the inert gas purge of the interior of the pod 1, if the inert gas is supplied from a deviated position such as an upper position of the pod 1, stagnation of the gas tends to occur in a region in the lower part of the pod 1, in particular near the opening portion 11a. In consequence, there is a possibility that it may be difficult to perform efficient purge or sufficient purge effect cannot be achieved unless a large amount of purge gas is continuously supplied. The apparatus according to the present invention can form the first gas flow A in a preferable manner by forming at least the second gas flow B and the third gas flow C in the state in which the lid 3 of the pod 1 is detached, whereby the oxygen partial pressure can be kept low as intended.

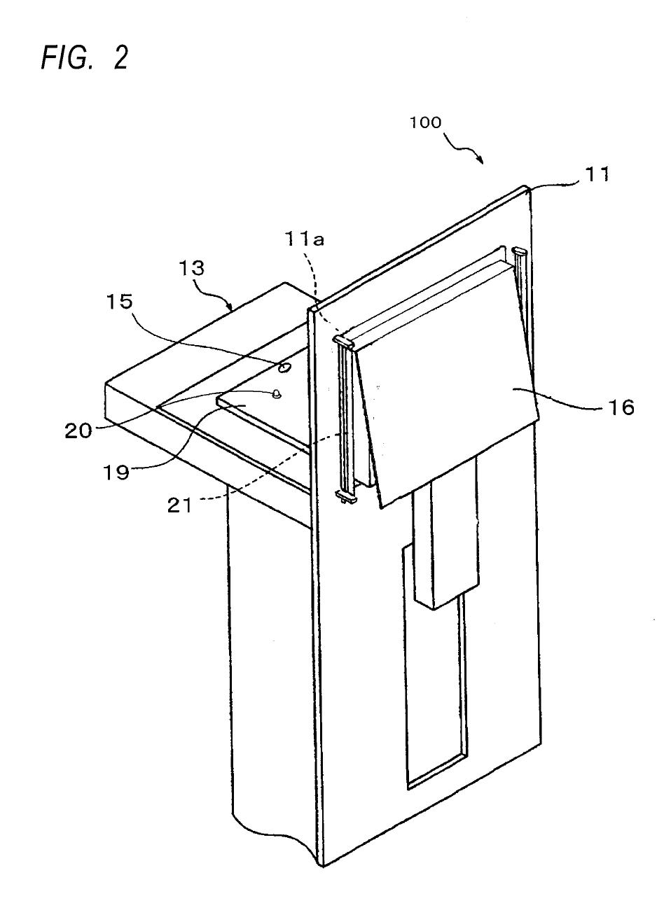

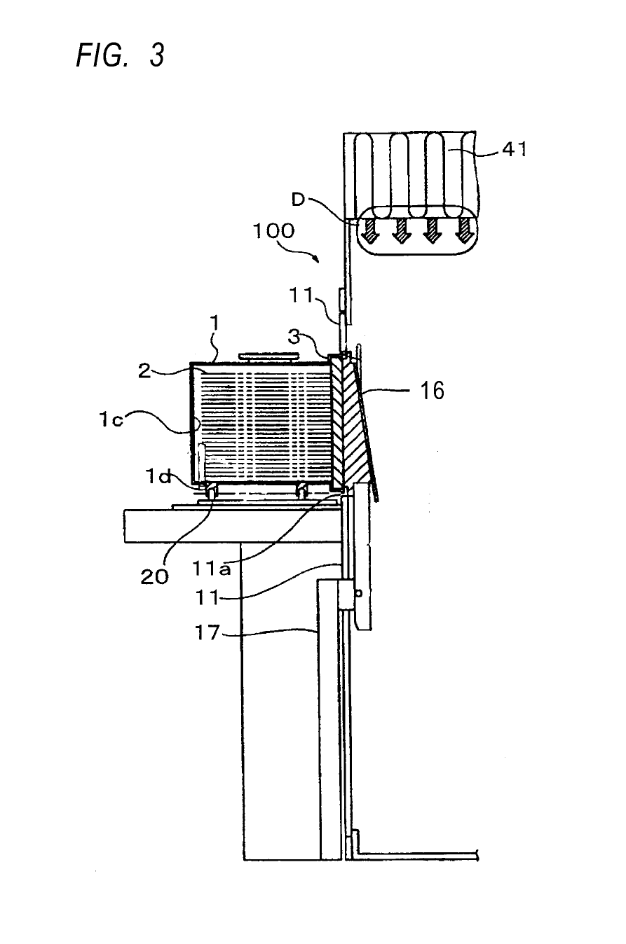

In the following, a specific embodiment of the present invention will be described with reference to the drawings. FIG. 2 is a perspective view showing the relevant portion of the load port apparatus according to an embodiment of the present invention. Components same as those described above are denoted by the same reference numerals and will not be described in further detail. FIG. shows components of the load port apparatus 100, which include a mount base 13, a door 16, a part of a door opening/closing mechanism 17 (see FIG. 3), and a wall 11 having an opening portion 11a, which partly defines the mini-environment. FIG. 3 is a cross sectional view schematically showing the load port 100 and the pod 1 in a state in which the pod 1 is set on the load port 100 (mount base 13) with the lid 3 of the pod 1 being in contact with the door 16.

The mount base 13 is provided with the aforementioned mount base gas supply ports 15, a movable plate 19, and positioning pins 20 (see FIG. 3). The pod 1 is actually mounted on the movable plate 19. The movable plate 19 can bring the pod 1 mounted thereon toward and away from the opening portion 11a. The movable plate 19 has a flat surface on its top, on which the pod 1 is mounted. The positioning pins 20 are planted on the flat surface of the movable plate 19. The positioning pins 20 engage positioning recesses 1d provided on the bottom of the pod 1 to determine the positional relationship of the pod 1 and the movable plate 19 uniquely. Moreover, when the pod 1 is mounted, the mount base gas supply ports 15 and the in-pod gas supply towers 1b come in communication with each other to establish a state in which inert gas can be supplied into the pod 1 through them. The in-pod gas supply towers 1b function as the in-pod gas supply ports in the present invention.

In the apparatus according to the present invention, a specific gas is supplied into the pod through the pod opening 1a with a specific flow rate distribution along the direction along which the wafers as plate-like contents are arranged in parallel to each other. The in-pod gas supply ports supply a specific gas from the side la opposite to the opening with a flow rate distribution corresponding to the predetermined flow rate distribution. Thus, the first gas flow A that flows along the side opposite to the opening and then flows to the opening of the pod is formed in the pod 1. In the direction along which the wafers 2 are arranged, the range over which the specific gas is blown out from the in-pod gas supply ports is smaller than the range over which the wafers 2 are arranged or smaller than the range over which the specific gas is blown out from the purge nozzles described later. In this embodiment, the range over which the gas is blown is between 30% and 70% of the inner height of the pod 1. By setting the range in this way, the first gas flow A is created satisfactorily.

In other words, the in-pod gas supply ports are arranged to extend into the interior of the pod from the bottom of the pod in the set state. The in-pod gas supply towers 1b may be arranged to extend from the ceiling or the bottom, which are parallel to the planes of the wafers in the pod. Although the illustrative case described above is preferable in view of down flow D, which will be described later, the in-pod gas supply towers 1b may be arranged to extend from a side of the pod, depending on factors such as the number of wafers housed in the pod. If the in-pod gas supply towers are arranged in this way, it is preferred that the direction in which the purge nozzles described later extend be changed accordingly.

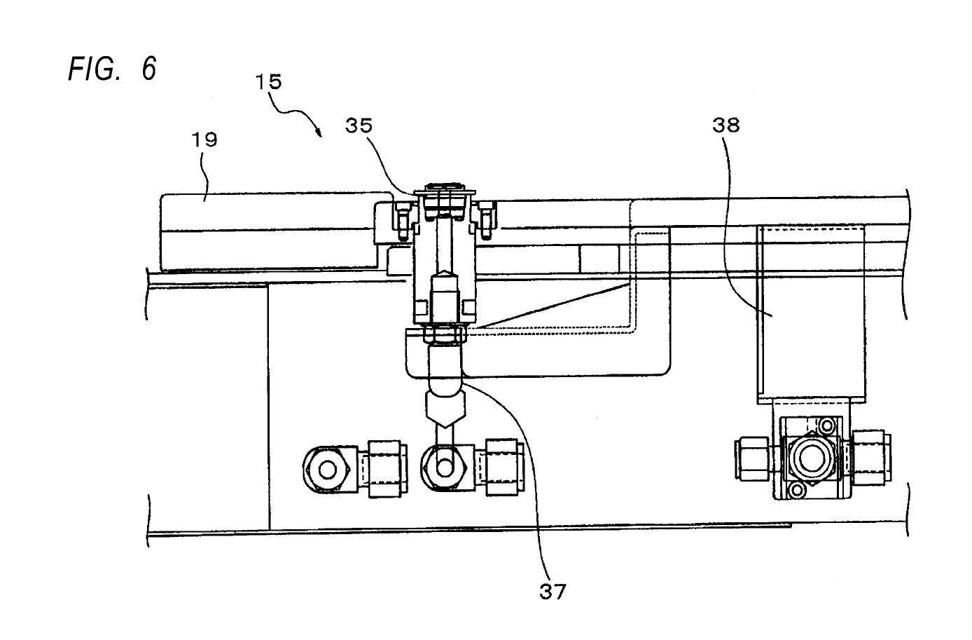

Now, the mount base gas supply ports 15 will be described with reference to FIG. 6, which is a vertical cross sectional view of the mount base 13 taken on a plane containing the ports 15. The mount base gas supply port 15 has a gas supply valve 35, which is a check valve that can supply gas only one-directionally. Inert gas is supplied to the gas supply valve 35 by an inert gas supply system not shown in the drawing through a gas supply pipe 37. The inert gas supply system can supply inert gas at a controlled pressure and controlled flow rate and can stop the supply of inert gas. The gas supply valve 35 is mounted on the mount base 13 by a valve up/down mechanism 38. The valve up/down mechanism 38 can shift the gas supply valve 35 between a supply position at which the gas supply valve 35 can supply inert gas to the pod 1 and a standby position at which the gas supply valve 35 does not supply inert gas and does not interfere with the bottom of the pod 1.

The opening portion 11a provided on the wall 11 is rectangular in shape and has a size that allows the lid 3 that closes the opening 1a of the pod 1 to fit into it when the pod 1 comes closest to the opening portion 11a. In other words, the size of the rectangular opening portion 11a is a little larger than the rectangular outer shape of the lid 3. The movable plate 19 sets the pod 1 stationary at a position that allows the door 16 to detach the lid 3 of the pod 1 from the pod body. The door 16 is supported by the door opening/closing mechanism 17 via a door arm. The door opening/closing mechanism 17 can move the door 16 between a position at which the door 16 substantially closes the opening portion 11a and a retracted position at which the door 16 leaves the opening portion 11a open fully to allow a transfer mechanism (not shown) to transfer wafers 2 into/out of the pod 1 through the opening portion 11a.

The purge nozzles 21 that supply inert gas into the pod 1 for purging are arranged in the mini-environment on both sides of the opening portion 11a. Each of the purge nozzles 21 has a tubular purge nozzle body extending in one direction and is connected to a purge gas supply system, which is not shown in the drawings. More specifically, the purge nozzle bodies are arranged on the side of the wall 11 opposite to the side of the mount base 13, on which the pod 1 is mounted. The purge nozzle bodies are provided in a pair at positions outside and adjacent to the opening portion 11a on both sides of the opening portion 11a and extend parallel to the sides of the opening portion 11a. Although the apparatus of this embodiment has two purge nozzles 21, the number of purge nozzles 21 is not limited to two. For example, the apparatus may have only one purge nozzle 21 if the aforementioned first gas flow A can be created by the cooperation of the inert gas supplied by the in-pod gas supply towers 1b and the inert gas supplied by the purge nozzle 21.

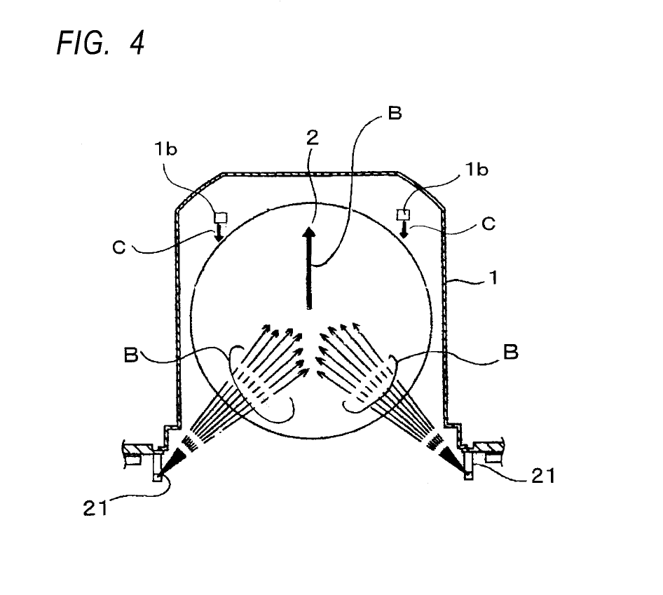

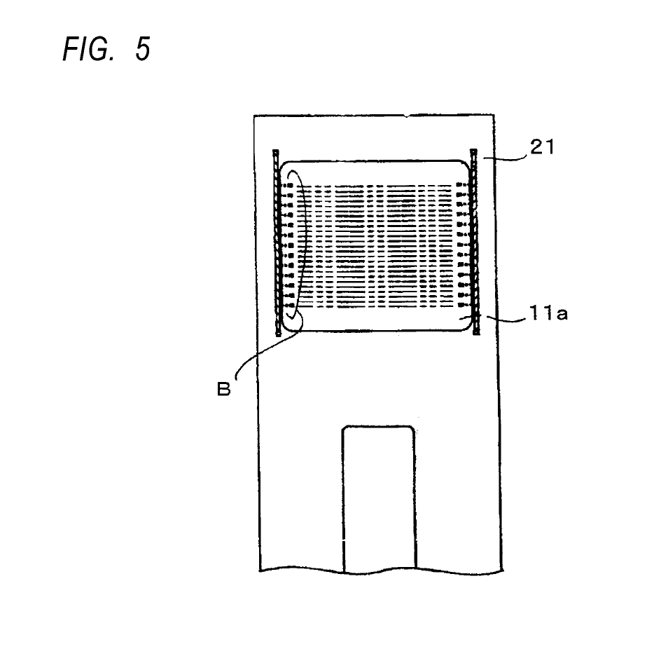

FIG. 4 is a diagram schematically showing the purge nozzles 21, the pod 1, and the wafers 2 seem from above, and FIG. 5 is a diagram schematically showing these components seen from the mini-environment side. The purge nozzle 21 is provided with a purge nozzle opening extending over a range corresponding to or larger than the range over which the wafers 2 in the pod 1 are arranged. The purge nozzle opening is arranged to be directed to the center of the wafers 2 in the pod 1. In other words, it is preferred that the direction of the center line of the second gas flow B of the inert gas supplied through the purge nozzle 21 be parallel to a plane perpendicular to the direction of gas supply from the purge nozzle 21 and be directed to a point equidistant from the two purge nozzles 21 in this plane. The two gas flows from the purge nozzles merge to create the second gas flow B from the pod opening 1a to the side 1c opposite to the opening extending over a large area on the wafers 2.

In a case, for example, where already processed wafers are housed in the pod 1 and the already processed wafers are transferred out of the pod 1, gas used in the processing and adhering to the wafer surface may be detached from the wafer surface to contaminate the interior of the pod 1. In the apparatus according to the present invention, the detached gas is removed from the neighborhood of the wafer surface by the second gas flow B formed by the purge gas and brought toward the far side of the pod 1 or the side 1c opposite to the opening. The aforementioned gas is brought along the side 1c opposite to the opening by the first gas flow A resulting from the second gas flow B and the third gas flow C and discharge out of the pod 1 along a gas discharge path formed by these gas flows. The gas discharged out of the pod 1 is brought to the lower part of the mini-environment and then to the external space by down flow D created by a fan filter unit 41 provided above the mini-environment. Thus, creating the multiple gas flows at the same time can provide purging of the interior of the pod 1 housing already processed wafers with improved efficiency.

In the apparatus according to the present invention, even when the lid 3 of the pod 1 is open and external gas can enter into the interior of the pod 1, it is possible to prevent a rise in the partial pressure of oxidative gases by continuously supplying a relatively small quantity of gas. For example, in prior art apparatuses, even if the processing time of a single wafer is not so long, it is necessary to close the lid 3 to reduce the oxygen partial pressure while waiting the completion of processing. In contrast, in the apparatus according to the present invention, the partial pressure of oxidative gases is kept smaller than a predetermined level even if the waiting state continues for a longtime, and the quality of all the wafers in the pod can be maintained uniformly. Moreover, it is possible to perform processing of wafers consecutively while leaving the lid 3 open. Consequently, reduction in the processing time and reduction in the load on the apparatus can also be achieved advantageously.

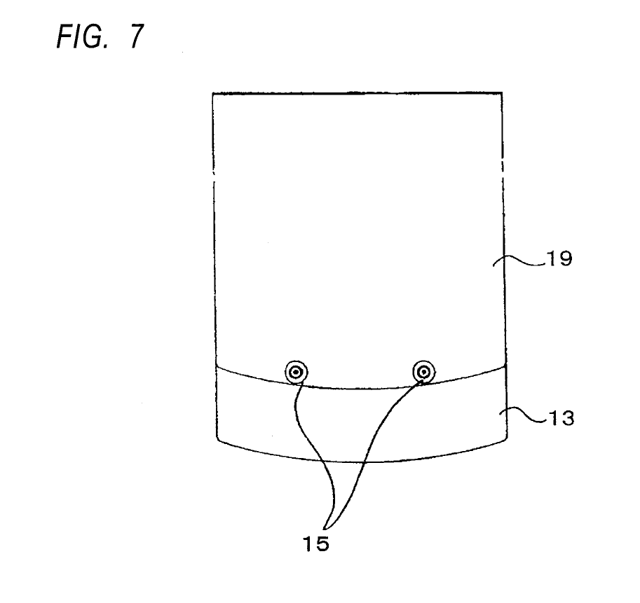

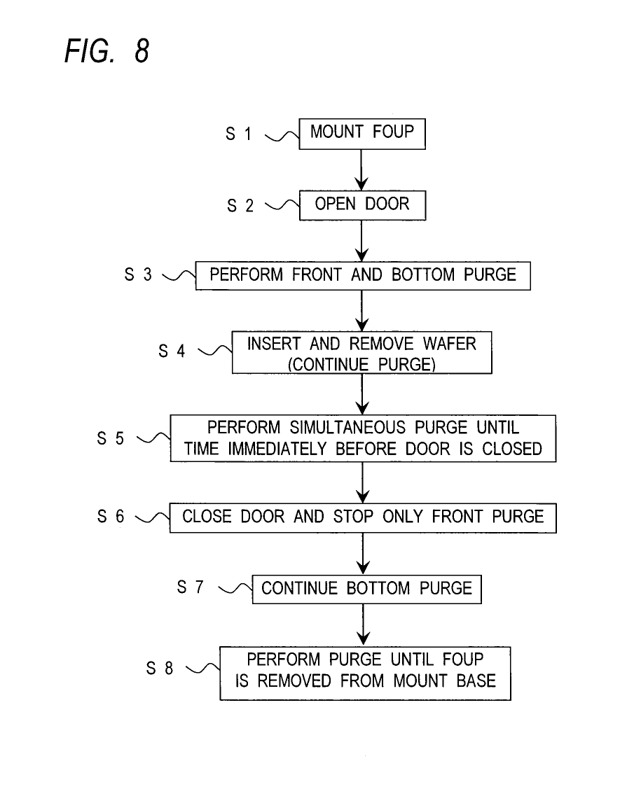

As with the mount base gas supply ports 15, the gas supply channel for supplying inert gas to the purge nozzles 21 is also connected to an inert gas supply system that can supply inert gas at a controlled pressure and controlled flow rate and can stop the supply of inert gas. Therefore, it is possible to change the flow rate of inert gas supplied through the nozzles to make taking into consideration the internal volume and internal shape of the pod 1, the number of wafers housed therein, and the mode of housing. It is preferred that the mount base gas supply ports 15 be located close to the side 1c of the pod 1 opposite to the opening as shown in FIG. 7 and in the vicinity of corner region of the inner wall of the pod 1 so that the third gas flow C which can cooperate with the second gas flow B to create the first gas flow A effectively as shown in FIG. 1. However, as described above, the location of the mount base gas supply ports 15 need not be limited particularly. What is essential is that the first gas flow A by which the gas having passed through the spaces between the wafers 2 is discharged along the inner wall of the pod can be created.

In the embodiment, two in-pod gas supply towers 1b having the same shape are arranged symmetrically with respect to the center line of the pod 1. However, this arrangement may be modified. For example, one of them may be shifted closer to the side wall and the other may be shifted away from the side wall, if their shifts do not lead to interfere with the wafers 2 housed in the pod. Furthermore, the two in-pod gas supply towers 1b may be different from each other in terms of the tower height or the inert gas supply range along the height direction. The aforementioned modifications may be made in combination so long as the third gas flow C resulting from the inert gas flows supplied by the in-pod gas supply towers 1b and the second gas flow B formed by inert gas supplied by the purge nozzles 21 cooperate to create the first gas flow A that is effective for purging the interior of the pod 1.

In the following, the operation of the above-described apparatus in the actual process of transferring the wafers 2 into/out of the pod 1 will be described. FIG. is a flow chart of the operation of the load port apparatus 100 during the transferring process. Firstly in step S1, the pod 1 is mounted on the mount base 13. At this time, the opening portion 11a is substantially closed by the door 16. After the pod 1 is mounted, the movable plate 19 moves toward the opening portion 11a and stops at the position that makes the lid 3 abut the door 16. The door 16 holds the lid 3 by an engagement mechanism not shown in the drawings, detaches the lid 3 from the pod 1, and is retracted away from the opening portion 11a downwardly, in step S2. The down flow D is created by the fan filter unit 41 all the time before the pod 1 is mounted on the mount base.

During or after the completion of the retraction of the door 16 by the door opening/closing mechanism 17 in step 2, purging of the interior of the pod 1 with inert gas by the purge nozzles 21 and purging with inert gas by the in-pod gas supply towers 1b are started (step S3). In this state, the opening 1a of the pod 1 is open, and transferring of wafers 2 into/out of the pod 1 by the transfer mechanism (not shown) provided in the mini-environment can be performed through the opening 11a. This state is maintained while transfer of the wafers 2 into/out of the pod 1 (inserting the wafer 2 into the pod 1 or removing the wafer 2 from the pod 1) in step S4 and processing on the wafers 2 are performed.

In this state, transfer of the wafers 2 is performed consecutively. During the transferring operation, the simultaneous purge until time immediately before door is closed, or the purging for the interior of the pod 1 is performed continuously to keep the oxygen partial pressure in the pod low (step S5). After completion of the operation of transferring of the wafers 2 to be housed in the pod 1, the operation of closing the lid 3 is performed in step S6. During this process, only supply of inert gas through the purge nozzles 21 is stopped, while supply of inert gas through the mount base gas supply ports 15 is continued. This operation is performed by the inert gas supply system for the purge nozzles 21, the inert gas supply system for the mount base gas supply ports 15, and control means for controlling these systems.

The control means controls the inert gas supply systems to supply inert gas into the pod 1 through the purge nozzles 21 and the mount base gas supply ports 15 at the same time in a certain time period in the state in which the lid 3 is detached from the pod 1 by the door 16. The control means includes opening/closing detection means for detecting opening/closing of the opening 1a with the lid 3 by the door 16 and means for starting supply of inert gas through the purge nozzles 21 in response to the closing of the opening 1a detected by the opening/closing detection means. By using these means, the apparatus can make the unnecessary supply of inert gas smaller than in the case where simple time-based control is performed, so that reduction in the consumption of the inert gas and reduction of dust blown up by unnecessary gas supply can be achieved.

In the above-described state, supply of inert gas into the pod 1 is performed for a predetermined period of time in step S7. Thus, the internal pressure in the pod 1 is kept higher than the atmospheric pressure by the inert gas, so that a state that can eliminate the possibility of entrance from atmosphere through the sealing of the lid 3. Thereafter, this state is maintained until the pod 1 is removed from the mount base 13 in step S8. As inert gas is supplied through the purge nozzles 21 and the mount base gas supply ports 15 at the same time by the control means, the first gas flow A resulting from the second gas flow B and the third gas flow C is appropriately created in the interior of the pod 1 from which the lid 3 has been removed, and uniform purging is achieved throughout the entirety of the internal space of the pod 1.

In the above-described embodiment, the mount base 13 is provided with only the gas supply ports 15. However, in cases where the sealing performance of the lid 3 is deteriorated over time or excessive supply of inert gas to the pod 1 in, for example, the above-described process of step S7, the deterioration in the sealing performance may need to be addressed in some cases. Therefore, gas may be discharged from the pod 1 whose internal pressure has been made high by the gas supply to create a flow of clean gas in the pod 1, thereby reducing the partial pressure of oxidative gases more effectively. In this case, it is preferred that ports for discharging gas be provided in addition to the mount base gas supply ports 15 provided on the mount base 13. The valve in each port may have a structure similar to that illustrated in FIG. 6, and ports cooperating with the valves are provided on the bottom of the pod 1.

While the apparatus of this embodiment is directed to the FOUP and the FIMS, the container and the system to which the present invention is applied are not limited to them. The lid opening/closing system according to the present invention can be applied to any front open type container in which a plurality of objects are housed and any system that opens/closes the lid of the container and transfers the object housed in the container into/out of it and can keep the partial pressure of oxidative gases in the interior of the container low. In cases where a specific gas having desired characteristics is used to fill the container instead of inert gas, the lid opening/closing system according to the present invention can be used to maintain the partial pressure of this specific gas inside the container high.

The system according to the present invention can effectively prevent or reduce the rise in the partial pressure of oxidative gases in the interior of the pod by supplying purge gas toward the wafers and supplying gas from the side of the pod opposite to the opening to form a circulative path of the supplied gas in the pod. The system according to the present invention can be realized by additionally providing a curtain nozzle, purge nozzle, and port for bottom purge etc. to an existing FIMS system. Such system can easily be provided to standardized systems at low cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-030354, filed Feb. 20, 2014, which is hereby incorporated by reference herein in its entirety.

What is claimed is:

1. A purge system comprising:
a pod for housing contents; and
a load port apparatus that performs an operation of purging gas in the interior of said pod, wherein
said pod has an opening leading to a space in which said contents are housed, a lid closing said opening, and an in-pod gas supply port arranged at a corner on the side opposite to said opening in said housing space and blowing a specific gas in a direction parallel to a direction in which said contents extend,
said load port apparatus is adapted to detach said lid from the pod thereby opening said opening and allowing transfer of said contents into/out of the pod and has a mount base on which said pod is mounted, a mini-environment arranged adjacent to said mount base in which a mechanism for transferring said contents is accommodated, an opening portion that is provided on a wall that is adjacent to said mount base and partly defines said mini-environment and able to directly face said opening of said pod mounted on said mount base, a door that can hold said lid, close said opening portion, and open said opening portion while holding said lid to thereby bring the interior of said pod and said mini-environment into communication with each other, a supply port that cooperates with said in-pod gas supply port to supply said specific gas into the interior of said pod, and a purge nozzle arranged on the mini-environment side of said opening portion near a side edge of said opening portion to supply said specific gas to the interior of said pod on/from which said lid is attached/detached,
said specific gas supplied through said in-pod gas supply port and said specific gas supplied through said purge nozzle each have a non-uniform flow rate distribution along a direction of arrangement of said contents when blown from them, and
a gas flow flowing along the side of said pod opposite to said opening and then flowing to said opening of said pod is created in said pod by the supplied gas flows having said non-uniform flow rate distribution.

2. A purge system according to claim 1, wherein a range over which said specific gas is blown out of said in-pod gas supply port is narrower than a range over which said specific gas is blown out of said purge nozzle.

3. A purge system according to claim 1, wherein said in-pod gas supply port extends from one of the inner surfaces of said pod extending parallel to planes in which said contents each having a plate-like shape extend in said pod.

4. A pod that allows transfer of contents into/out of it through an opening, comprising:
a lid that closes said opening; and
an in-pod gas supply port that supplies, when a specific gas is supplied into the pod through said opening with a predetermined flow rate distribution along an arrangement direction along which said contents each having a plate-like shape are arranged in parallel to each other, said specific gas from a side of the pod opposite to said opening with a flow rate distribution corresponding to said predetermined flow rate distribution in said arrangement direction, thereby creating in said pod a gas flow flowing along the side opposite to said opening and then flowing to the opening of said pod.

5. A pod according to claim 4, wherein a range over which said specific gas is blown out of said in-pod gas supply port is narrower than a range over which said contents are arranged in said arrangement direction.

6. A pod according to claim 5, wherein said in-pod gas supply port is arranged to extend from the bottom of said pod into the interior of the pod when the pod is mounted on a plane extending in parallel with said contents.

7. A load port apparatus that performs an operation of purging gas in the interior of a pod according to claim 4 with gas, comprising:
a mount base on which said pod is mounted;
a mini-environment arranged adjacent to said mount base in which a mechanism for transferring said contents is accommodated;
an opening portion that is provided on a wall that is adjacent to said mount base and partly defines said mini-environment and able to directly face said opening of said pod mounted on said mount base;
a door that can hold said lid, close said opening portion, and open said opening portion while holding said lid to thereby bring the interior of said pod and said mini-environment into communication with each other;
a supply port that cooperates with said in-pod gas supply port to supply said specific gas into the interior of said pod; and
a purge nozzle arranged on the mini-environment side of said opening portion near a side edge of said opening portion to supply said specific gas to the interior of said pod on/from which said lid is attached/detached,
wherein said purge nozzle supplies a specific gas into the interior of said pod through said opening with a predetermined flow rate distribution.
